(19) United States
(12) Patent Application Publication
(10) Pub. No.: US 2025/0113648 A1
(43) Pub. Date: Apr. 3, 2025

(54) VAN DER WAALS QUANTUM DOTS

(71) Applicant: The Regents of the University of Michigan, Ann Arbor, MI (US)

(72) Inventors: Zetian Mi, Ann Arbor, MI (US); Yuanpeng Wu, Ann Arbor, MI (US); Yixin Xiao, Ann Arbor, MI (US)

(21) Appl. No.: 18/847,093

(22) PCT Filed: Mar. 16, 2023
(86) PCT No.: PCT/US2023/015378

§ 371 Date: Sep. 13, 2024

Related U.S. Application Data
(60) Provisional application No. 63/320,462, filed on Mar. 16, 2022.

(51) Int. Cl. H10F 77/14; B82Y 20/00; B82Y 40/00; C01B 21/06; C01B 21/064; H10F 71/00

(52) U.S. Cl. CPC H10F 77/1433; C01B 21/0632; C01B 21/064; H10F 71/1278; B82Y 20/00; B82Y 40/00; C01P 2002/76; C01P 2004/03; C01P 2004/04; C01P 2004/20; C01P 2006/40; C01P 2006/60

(57) ABSTRACT

A device includes a substrate and a heterostructure supported by the substrate. The heterostructure includes a set of quantum dot structures, each quantum dot structure of the set of quantum dot structures including a semiconductor material, and a layered material disposed between the set of quantum dot structures and the substrate. The layered material includes a plurality of monolayers such that adjacent monolayers of the plurality of monolayers are bonded to one another via van der Waals forces, and the semiconductor material of each quantum dot structure of the set of quantum dot structures exhibits bonding via van der Waals forces.

### CROSS-REFERENCE TO RELATED APPLICATION

This application claims the benefit of U.S. provisional application entitled “van der Waals Quantum Dots,” filed Mar. 16, 2022, and assigned Ser. No. 63/320,462, the entire disclosure of which is hereby expressly incorporated by reference.

### STATEMENT REGARDING FEDERALLY SPONSORED RESEARCH OR DEVELOPMENT

This invention was made with government support under Contract No. 2118809 awarded by the National Science Foundation. The government has certain rights in the invention.

### BACKGROUND OF THE DISCLOSURE

### Field of the Disclosure

The disclosure relates generally to semiconductor quantum dots and nanocrystals.

### Brief Description of Related Technology

Semiconductor quantum dots (QDs) have potential applications in the field of integrated quantum optics including quantum-computing, quantum key distribution and secure data transmission. To date, QDs have been extensively studied for applications in single photon source, two-photon interference, and polarization entanglement. Epitaxial QDs have been proven to be promising quantum light emitters due to their scalability and integrability. The achievement of semiconductor QDs can be based on either advanced lithography, epitaxial techniques, or solution processing. Since a top-down process potentially introduces sidewall damages which lead to nonradiative recombination process, a bottom-up epitaxy process is more preferable for fabricating QDs. To date, several strategies have been utilized to grow QDs, including droplet epitaxy, Stranski-Krastanov (SK), or related processes, among which the SK growth mode has been commonly used for the synthesis of III-V semiconductor QD heterostructures.

For the extensively studied InAs/GaAs system, which has about a 7% lattice mismatch, SK growth manifests itself as an initial layer-by-layer growth with the formation of a two-dimensional (2D) wetting layer, followed by the formation of 3D dot-like structure above the InAs wetting layer. This approach, however, has several fundamental limitations. First, the presence of the wetting layer significantly reduces charge carrier confinement and introduces undesirable properties, including the hot carrier effect and reduced luminescence efficiency. Second, the optical properties of QDs have been shown to be greatly affected by the dislocation density within the substrate. For example, InGaAs quantum wells (QWs) grown on GaAs/Si with threading dislocation density of about 10⁶-10⁸ cm⁻² show about 10 times reduction in luminescence intensity compared to QWs grown on bulk GaAs. The issue further deteriorates with III-nitride systems due to a lack of intrinsic substrates while foreign substrates typically show a large lattice mismatch and thermal expansion coefficient mismatch with the grown layers. The threading dislocation density of AlN grown on c-plane sapphire can be as high as 10¹¹ cm⁻², which is comparable to the reported density of GaN QDs spontaneously assembled on an AlN substrate.

### SUMMARY OF THE DISCLOSURE

In accordance with one aspect of the disclosure, a device includes a substrate and a heterostructure supported by the substrate, the heterostructure including a set of quantum dot structures, each quantum dot structure of the set of quantum dot structures including a semiconductor material, and a layered material disposed between the set of quantum dot structures and the substrate. The layered material includes a plurality of monolayers such that adjacent monolayers of the plurality of monolayers are bonded to one another via van der Waals forces, and the semiconductor material of each quantum dot structure of the set of quantum dot structures exhibits bonding with the layered material via van der Waals forces.

In accordance with another aspect of the disclosure, a method of fabricating a quantum dot device includes forming a layered material, the layered material including a plurality of monolayers supported by a substrate, with adjacent monolayers of the plurality of monolayers being bonded to one another via van der Waals forces, and growing epitaxially a set of quantum dot structures, each quantum dot structure of the set of quantum dot structures including a semiconductor material. Growing the set of quantum dot structures is implemented after forming the layered material such that the layered material is disposed between the set of quantum dot structures and the substrate, and the semiconductor material of each quantum dot structure of the set of quantum dot structures exhibits bonding with the layered material via van der Waals forces.

In accordance with still another aspect of the disclosure, a device includes a substrate and a heterostructure supported by the substrate, the heterostructure including a set of nanocrystals, each nanocrystal of the set of nanocrystals including a semiconductor material, and a layered material disposed between the set of nanocrystals and the substrate. The layered material includes a plurality of monolayers such that adjacent monolayers of the plurality of monolayers are bonded to one another via van der Waals forces, and the semiconductor material of each nanocrystal of the set of nanocrystals exhibits bonding with the layered material via van der Waals forces.

In accordance with yet aspect of the disclosure, a method of fabricating a device includes forming a layered material, the layered material including a plurality of monolayers supported by a substrate, with adjacent monolayers of the plurality of monolayers being bonded to one another via van der Waals forces, and growing epitaxially a set of nanocrystals, each nanocrystal of the set of nanocrystals including a semiconductor material. Growing the set of nanocrystals is implemented after forming the layered material such that the layered material is disposed between the set of nanocrystals and the substrate, and the semiconductor material of each nanocrystal of the set of nanocrystals exhibits bonding with the layered material via van der Waals forces.

In accordance with still another aspect of the disclosure, a device includes a substrate and a set of quantum dot structures supported by the substrate. Each quantum dot structure of the set of quantum dot structures includes a semiconductor material. The semiconductor material of each quantum dot structure of the set of quantum dot structures exhibits bonding with the substrate via van der Waals forces.

In connection with any one of the aforementioned aspects, the devices and/or methods described herein may alternatively or additionally include or involve any combination of one or more of the following aspects or features. The substrate includes a covalently bonded material. The layered material has a number of monolayers sufficient to screen the set of quantum dot structures from a potential field of the covalently bonded material. The heterostructure lacks a wetting layer. Each quantum dot structure of the set of quantum dot structures is bonded to one of the plurality of monolayers via van der Waals forces. The quantum dot structures exhibit multiple crystallographic orientations. The heterostructure is in contact with the substrate. Each quantum dot structure of the set of quantum dot structures is in contact with a first monolayer of the plurality of monolayers. A second monolayer of the plurality of monolayers is in contact with the substrate. The semiconductor material is a III-V material. The semiconductor material is a III-nitride material. The semiconductor material is GaN. The layered material is hexagonal boron nitride. The substrate includes polycrystalline nickel. The substrate and the layered material have a chemical composition in common. The semiconductor material includes a III-nitride material, and growing the set of quantum dot structures is implemented in a nitrogen-rich environment. Growing the set of quantum dot structures is implemented at a temperature falling in a range from about 600° C. to about 850° C. degrees Celsius. Forming the layered material includes epitaxially growing the layered material. Epitaxially growing the layered material includes implementing a growth procedure configured for van der Waals epitaxy. The substrate includes a covalently bonded material, and epitaxially growing the layered material includes implementing a growth procedure configured to grow a number of monolayers sufficient to screen the set of quantum dot structures from a potential field of the covalently bonded material. The set of quantum dot structures are not grown upon a wetting layer. The set of quantum dot structures are in contact with the substrate. The substrate includes silicon. The substrate is transparent.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts a scanning electron microscope (SEM) image of an example heterostructure with a layered material (e.g., hexagonal boron nitride, or hBN) and gallium droplets formed thereon, as well as a bright-field scanning transmission electron microscope (STEM) image of a portion of the heterostructure, a high magnification STEM image of the layered material, and a schematic view of a quantum dot device having a heterostructure in accordance with one example.

FIG. 2 depicts an SEM image of a GaN quantum dot/hBN heterostructure in accordance with one example, as well as a high magnification SEM image of a portion of the heterostructure, an atomic force microscope (AFM) height image of an hBN layer, a bright-field STEM image of a GaN quantum dot structure on hBN, FFT analysis of the quantum dot structure, a high magnification STEM image of the hBN layered material showing about five monolayers, and EDS mapping of Ga, N, and Ni signals.

FIG. 3 depicts SEM images of GaN quantum dots grown on hBN in accordance with two examples, as well as AFM height images of GaN quantum dots grown on hBN in accordance with two examples.

FIG. 4 depicts an SEM image of example nanocrystals grown on hBN, as well as a low magnification SEM image of a triangular hBN flake with GaN nanocrystals thereon, a schematic view of the crystallographic orientation between horizontal GaN nanocrystals and a hBN layer, and a schematic view of the crystallographic orientation between vertical GaN nanocrystals and a hBN layer.

FIG. 5 depicts graphical plots of photoluminescence (PL) spectra of GaN quantum dots on hBN, AlN and SiNₓ layers or substrates, as well as graphical plots of temperature-dependent peak emission energies of GaN quantum dots on AlN and on hBN, and the generation rate versus integrated PL intensity of the emissions from the GaN quantum dots on hBN and AlN layers or substrates.

FIG. 6 is a flow diagram of a method of fabricating a quantum dot device in accordance with one example.

FIG. 7 depicts (a) a schematic illustration of mechanical exfoliation of GaN quantum dot structures from a set of hBN monolayers, (b) a SEM image of GaN quantum dot/hBN heterostructure before exfoliation, in which a dashed rectangle encloses the area where the GaN quantum dot structures are covered by a deposited carbon film (for confirmation purposes), and (c) a SEM image of the heterostructure after exfoliation, with the dashed rectangle indicating the same area as in the SEM image of part (b) for comparison.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices having a set of semiconductor quantum dots or nanocrystals are described. The disclosed devices include a heterostructure having a layered material disposed between quantum dot structures (or nanocrystals) and a substrate. The layered material includes a plurality of monolayers bonded to one another via van der Waals forces. As a result, the semiconductor material of each quantum dot (or nanocrystal) also exhibits bonding with the layered material via van der Waals forces. In some cases, the disclosed devices and methods include or involve van der Waals quantum dots (or nanocrystals) grown on multiple monolayers of hexagonal boron nitride (hBN). Methods of fabricating such quantum dot and other devices via epitaxial growth procedures are also described.

The layered material may have a number of monolayers sufficient to screen the quantum dot structures (or nanocrystals) from a potential field of the substrate. For instance, the substrate may be composed of a covalently bonded material. During epitaxial growth of the quantum dot structures (or nanocrystals), the semiconductor material of the quantum dots (or nanocrystals) is shielded from the potential field from the covalent bonds by the monolayers. As a result, the epitaxial growth of the quantum dots (or nanocrystals) is governed by van der Waals interactions. Covalent epitaxial growth is thus avoided.

The issues noted above can be addressed in van der Waals (vdW) based heterostructures, in which the atomic interactions between the grown materials and substrates are significantly weakened. This weak interaction has enabled the successful exfoliation of III-V optoelectronic materials epitaxially integrated on substrates coated by 2D materials such as graphene and hBN, which has shown promising applications for next-generation flexible and wearable devices. Moreover, it has been shown that the potential field from covalent-bonded substrates can be screened by a monolayer of graphene although that from ionic-bonded substrates can penetrate through a few layers of graphene. Such field penetration can be substantially attenuated by two-dimensional (2D) hexagonal boron nitride (hBN), a compound semiconductor with a hexagonal type crystalline structure and strong, in-plane, sp² ionic bonding. hBN has been shown to be the best insulating material to enhance the mobility of graphene and can significantly suppress the carrier inhomogeneities in transition metal dichalcogenides.

As described herein, vdW based heterostructures are used to support the synthesis of vdW bonded QDs and nanocrystals.

Described herein are examples of complete vdW epitaxy of GaN. Such epitaxy is achieved when the thickness of hBN on polycrystalline nickel is equal to, or above, two monolayers. Such epitaxy may be implemented under nitrogen-rich growth conditions instead of the conventional metal-rich growth conditions. The examples establish the successful demonstration of epitaxy and morphology control of wetting layer free GaN QDs on layered hBN. Detailed structural characterizations show that GaN QDs are free of threading dislocations and stacking faults. Unlike QDs covalently bonded to substrates, multiple crystallographic orientations were observed in QDs bonded with hBN through vdW interactions. Highly efficient radiative recombination process was measured from GaN QDs on hBN with the photoluminescence (PL) emission intensity 4 times stronger compared with QDs synthesized on AlN and Si substrates while the QD density on hBN is nearly two orders of magnitude lower, confirming the extremely high quality of van der Waals GaN QDs grown on a plurality of monolayers of hBN (e.g., few layer hBN).

Although described in connection with light emitting and/or optoelectronic devices, the disclosed methods and devices may be applied to a wide variety of electronic and other devices. For instance, the disclosed devices may be configured for quantum computing and other electronic functions and applications.

Although described in connection with examples having GaN quantum dot structures, the disclosed devices and methods may include or involve quantum dot structures of varying composition. For instance, the disclosed methods and devices may include or involve other III-nitride materials, other III-V materials, or other semiconductor materials. In some cases, the quantum dot structures are composed of, or otherwise include, III-nitride semiconductor materials, such as InN and AlN, as well as their alloys.

The compositions of other elements or components of the disclosed devices may also vary. For instance, the disclosed devices are not limited to a particular substrate material or a particular type of layered material disposed between the substrate and the quantum dot structures. While the disclosed devices and methods are described in connection with nickel substrates, other substrate materials may be used, including, for instance, graphene and graphite. While the disclosed devices and methods are described in connection with hBN monolayers, other layered materials may be used, including, for instance, Molybdenum disulfide (MoS₂), Molybdenum diselenide (MoSe₂), Tungsten disulfide (WS₂), Tungsten diselenide (WSe₂), and graphene.

The substrate of the disclosed devices may or may not correspond with the growth substrate, or the substrate on which the heterostructures of the disclosed devices are grown. For instance, the heterostructures may be transferred to another substrate, such as a GaN, Si, or sapphire substrate, after growth of the heterostructures.

The substrate may or may not have a composition in common with the layered material of the heterostructure. For instance, the substrate may be composed of, or otherwise include, graphene, silicon, sapphire, nickel, or copper, while the layered material may be composed of, or otherwise include, hexagonal BN (hBN), graphene, MoS₂, WS₂, or WSe₂.

The configuration, construction, fabrication, and other characteristics of the heterostructures may also vary from the examples described. For instance, the heterostructures may include any number of epitaxially grown layers.

Although described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition procedures.

In the examples described below, multiple monolayers of two-dimensional (2D), layered hBN were epitaxially grown on polycrystalline nickel in a Veeco GENxplor MBE system equipped with a radio frequency nitrogen plasma source and an e-beam source. Further details regarding the growth procedures of the hBN monolayers are provided below. The resulting hBN monolayers were configured as flakes, which feature triangular domains with dimensions of about 10 μm on the polycrystalline nickel. The number of layers is identifiable based upon the contrast in the imaged area. In these examples, the center of the hBN triangle was thicker than the edges. The as-grown samples were then transferred to a Veeco GEN II system for subsequent GaN epilayer/QD growth.

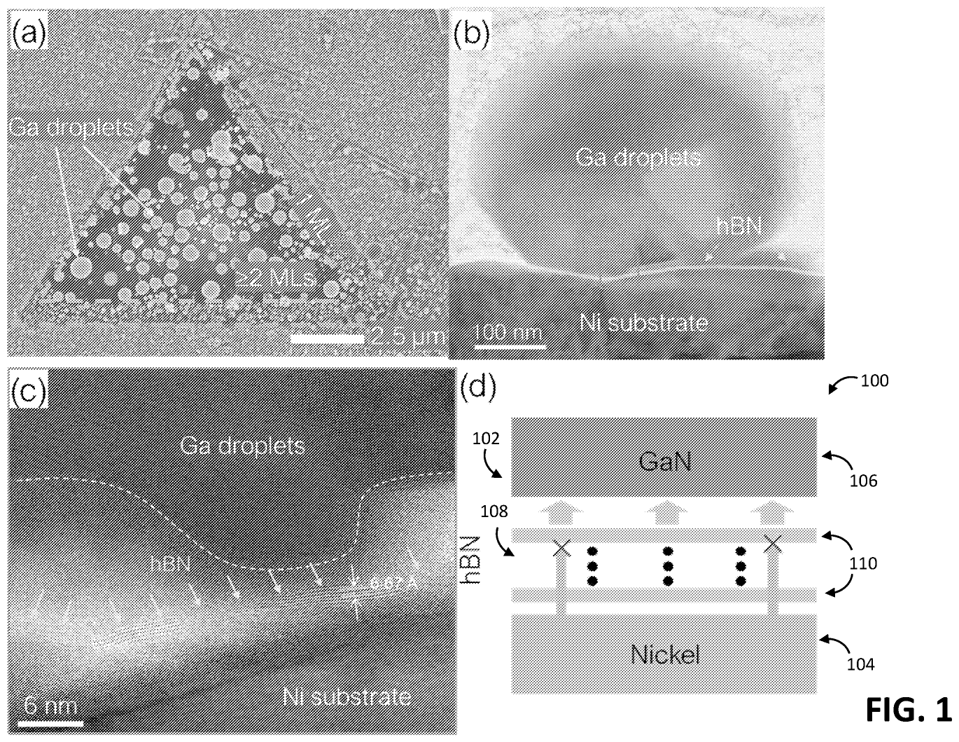

FIG. 1, part a, shows an SEM image of an example GaN QD/hBN heterostructure together with the formation of Ga droplets. The magenta dashed lines indicate the boundary of a hBN layered material. The green dashed lines outline the region where Ga droplets are present, which are indicated by the yellow arrows. Part (b) of FIG. 1 is a bright-field STEM image of the yellow boxed region in part (a), showing Ga droplet formation on top of hBN. Part (c) of FIG. 1 is a high-magnification STEM image of the hBN interlayer as indicated by the green arrows. The measured bi-interlayer distance is 6.67 Å.

Part (d) of FIG. 1 depicts a schematic view of a device 100 having a heterostructure 102 supported by a substrate 104. The heterostructure 102 includes a GaN QD structure 106 and hBN layered material 108 on which the GaN QD structure 106 is disposed. The hBN layered material 108 includes a number of monolayers 110. In this example, the hBN layered material 108 has a thickness equal to or greater than two monolayers. The red crosses are schematically indicative of how the potential field of the substrate 104 cannot penetrate through the multilayer hBN material 104.

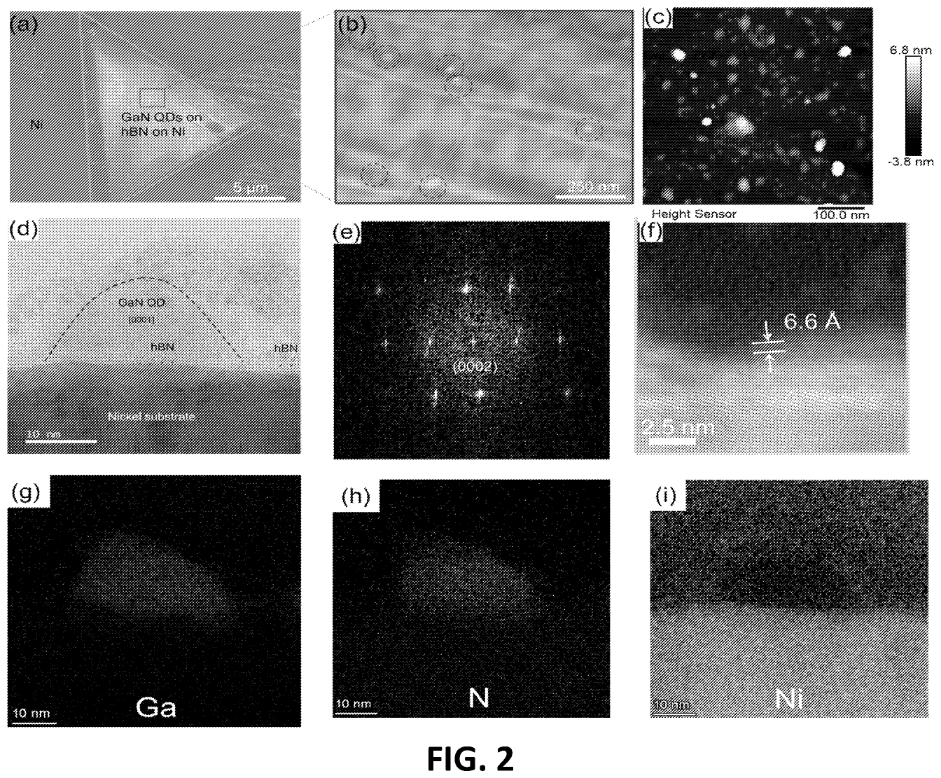

FIG. 2, part a, shows an SEM image of an example GaN QD/hBN heterostructure. The green lines indicate the boundary of hBN. Part (b) is a high-magnification SEM image of the red boxed region in part (a). The red dashed circles indicate the GaN QDs with sizes ranging from 5 to 25 nm. Part (c) is an AFM height image of a 500×500 nm² area of hBN on Ni substrate. Part (d) is a bright-field STEM image of GaN QD on hBN. The electron beam was aligned to the zone axis of nickel substrate. The profiles of GaN QDs outlined by purple dashed lines. The blue arrow indicates the c-axis of the grown GaN QD. Part (e) depicts FFT analysis of the GaN QD region shown in part (d). The measured c-lattice constant is 0.52 Å. Part (f) is a high-magnification STEM image showing hBN of about 5 monolayers. EDS mapping is shown in parts (g) Ga, (h) N, and (i) Ni, for signals of GaN QD on hBN.

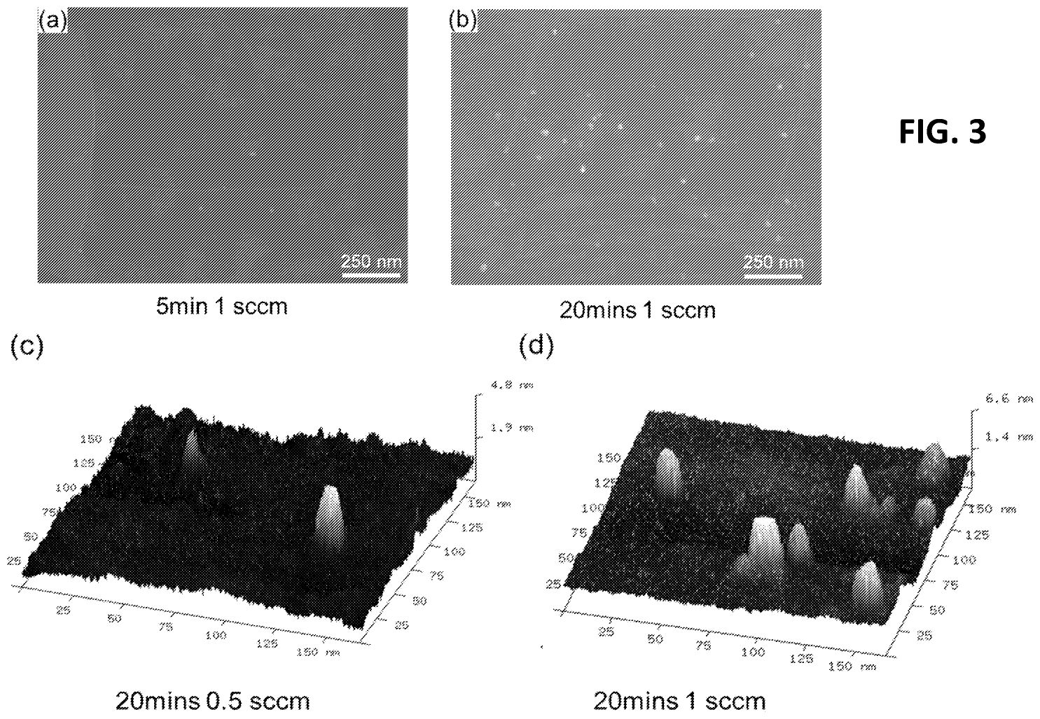

FIG. 3 shows SEM images of GaN QDs grown on hBN with a duration of 5 mins (part a) and 20 mins (part b) under a nitrogen flow rate of 1 sccm. Parts (c) and (d) show AFM height images of GaN QDs grown on hBN for a duration of 20 mins with a nitrogen flow rate of 0.5 sccm (part c) and 1 sccm (part d).

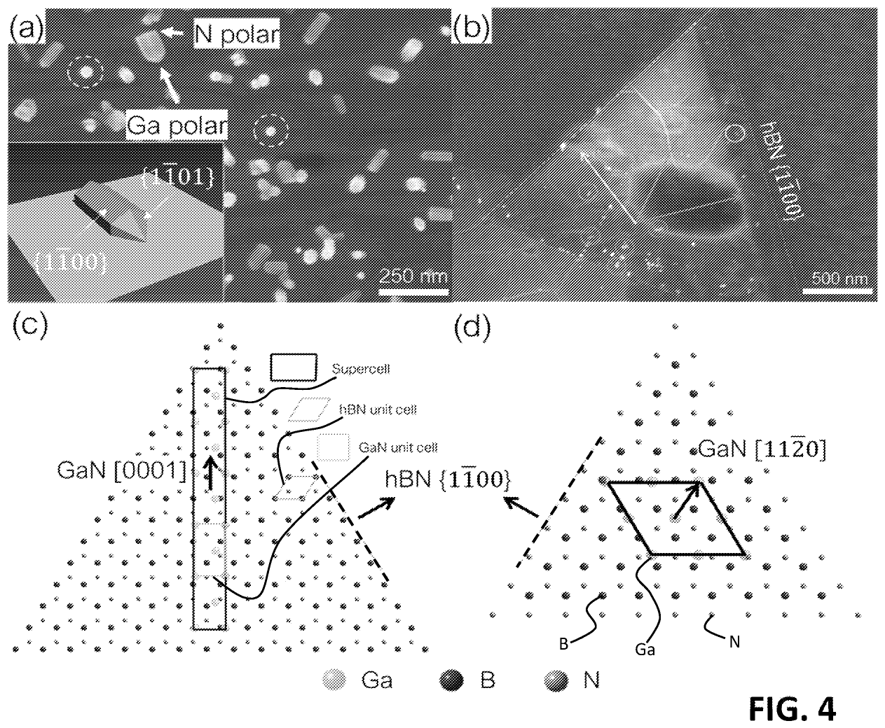

FIG. 4, part a, shows an SEM image of nanocrystals grown on hBN. The arrows point to the horizontal nanocrystals while the yellow dashed circles indicate the vertical nanocrystals. The inset is a schematic showing a faceted horizontal nanocrystal. Part (b) is a low magnification SEM image showing a triangular hBN flake with GaN nanocrystals on top. The c-axis of the circled nanocrystals are indicated by the three arrows. Part (c) is a schematic representation of the crystallographic orientation between horizontal GaN nanocrystals and the hBN layer. Part (d) is a schematic representation of the crystallographic orientation between vertical GaN nanocrystals and the hBN layer.

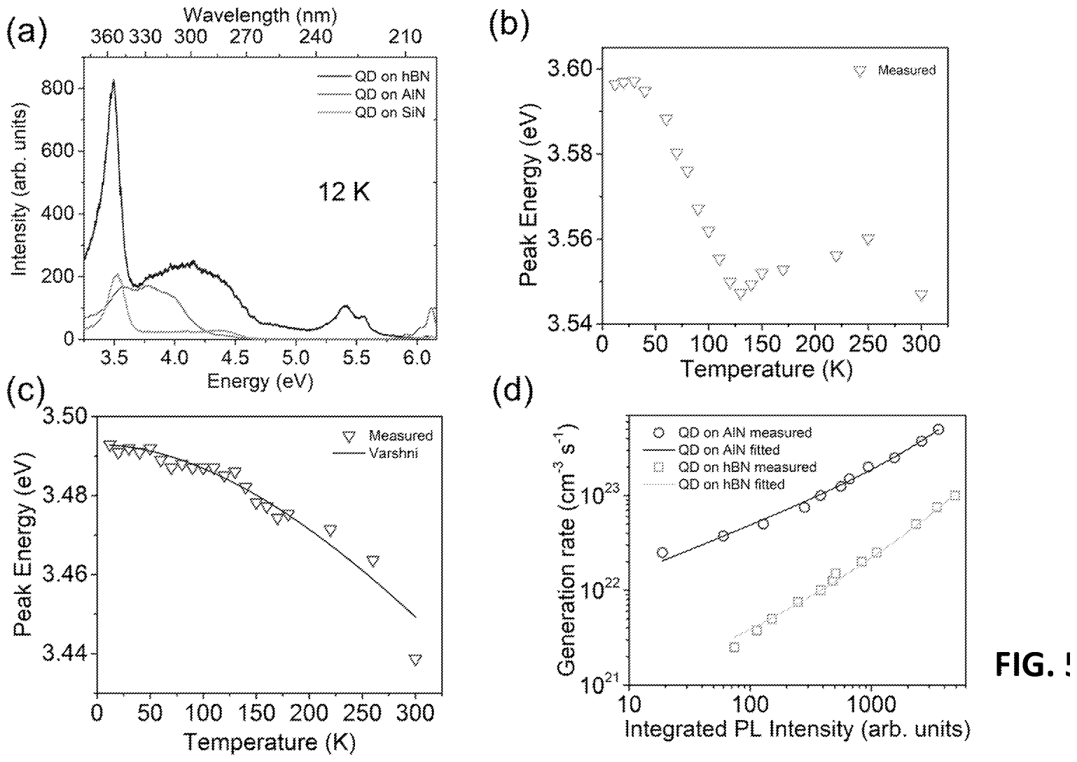

FIG. 5, part a, shows photoluminescence spectra of GaN QDs on hBN, AlN and SiNₓ measured at 12 K under an excitation power density of 20 W/cm². Part (b) shows the temperature-dependent peak emission energies of GaN QDs on AlN. Part (c) shows the temperature-dependent peak emission energies of GaN QDs on hBN. The red curve is a fit to the experimental data through Varshni's law. Part (d) depicts the generation rate versus integrated PL intensity of the GaN QDs emission on hBN and AlN materials or substrates.

Further details regarding the subject matter of FIGS. 1-5 are provided below.

To identify the thickness of the hBN layered material that is capable of completely screening the potential field of the underlying polycrystalline nickel, the epitaxy of a GaN film was first attempted under conventional metal rich growth conditions. Detailed growth parameters are provided below. Based on the morphology differences across the as-grown materials, regions with and without hBN can be readily distinguished. As shown in FIG. 1 (part a), a quasi-film structure was formed outside the magenta dashed triangle which is the nickel without hBN coverage. Morphology variations were also observed within the magenta triangle, in which spherical droplets with sizes less than 2 μm were distributed (within the green triangle) and nanoparticles were formed between the green and magenta dashed lines. In-situ focused ion beam (FIB) sampling was performed along the [1120] direction of hBN.

FIG. 1 (part b) depicts a bright-field scanning transmission electron microcopy (STEM) image of the yellow boxed region in FIG. 1 (part a), in which a spherical Ga droplet can be identified on hBN on nickel. The existence of thin hBN layers on the surface of the nickel substrate was evidenced by a high magnification STEM image (FIG. 1, part c) of the Ga droplet/Ni interface (blue boxed region in FIG. 1, part b). About 5 layers (monolayers) of hBN were clearly identified as indicated by the yellow arrows. The bi-interlayer spacing of the layered hBN was measured to be 6.67 Å, which matches well with reported c-lattice constant of hBN.

Previous studies have shown that initial nucleation of GaN on hBN is almost impossible due to the sp² orbital hybridization of hBN and its absence of dangling bonds unless intentionally introducing defects through surface treatment such as plasma treatment. Therefore, the lack of nucleation establishes that the hBN is of pristine quality and low defect density. The nucleation and formation between the magenta and green dashed lines are likely due to the potential field of Ni substrate penetrating a single monolayer of hBN. Meanwhile, in regions where the hBN thickness is equal to or greater than two monolayers, the growth becomes complete vdW epitaxy, in which adatom nucleation, i.e., growth of GaN on hBN becomes extremely difficult under the conventional metal rich conditions, as shown in FIG. 1, part d.

Epitaxy of GaN QDs on the hBN layered material was performed under nitrogen rich conditions and elevated temperatures. In some case, the growth temperature falls in a range from about 600° C. to about 850° C., but other temperatures may be used in connection with, for instance, other semiconductor materials. Epitaxial growth of GaN QDs using similar conditions but on AlN and Si substrates was also performed for purposes of comparison. FIG. 2, part a is the low magnification SEM image of the as-grown GaN QDs on hBN using a 1 sccm nitrogen flow rate, in which white dot-like structures were observed on the surface of a triangular hBN flake. In contrast, no GaN formation was observed on nickel. FIG. 2, part b shows the magnified SEM image of the red boxed region in FIG. 2, part a, and the dot-like structure is indicated by the red dashed circles. QD formation was further confirmed by detailed AFM measurements as shown in FIG. 2, part c. The dot density is about 2.6×10⁹ cm⁻², which is nearly 2 orders of magnitude lower than the density of GaN QDs grown on AlN substrates using similar conditions. FIG. 2, part d is the low magnification bright-field STEM image of the GaN QD/hBN heterostructure, in which the

electron beam was aligned along the [11̅0] zone axis of the nickel substrate and hemispherical dotlike structures were seen atop as outlined by the purple dashed line. A hBN interlayer of about 3 monolayers is indicated by the purple arrows and shown in FIG. 2, part e. FIG. 2, parts g-i, show the electron dispersive spectroscopy (EDS) mappings of the nickel, gallium and nitrogen elements, respectively, which confirm the formation of GaN QDs. Multiple GaN QDs were characterized across the sample and both the STEM imaging and EDS mapping show no sign of formation of wetting layers, threading dislocations, or stacking faults. For comparison, in GaN QDs grown on AlN, prior to the formation of QDs, a GaN wetting layer with a thickness of about 2 nm was formed on top of the AlN substrate.

Crystallographic orientation between the GaN QDs and the hBN monolayers were characterized by detailed STEM imaging and fast Fourier transform (FFT) analysis. As shown in FIG. 2, part f, the GaN QD features wurtzite structure with a measured c-lattice constant of 5.2 Å, indicating the c-axis of the GaN QD is parallel to the in-plane direction of hBN as shown in FIG. 2, part a. Moreover, GaN QDs with c-axis parallel to the c-axis of hBN were also observed. Meanwhile, identical crystallographic alignment between GaN QDs and AlN was observed.

Morphology control of the GaN QDs on the hBN monolayers was investigated by varying the growth durations and III/N ratios with the corresponding dot density, mean aspect ratio and thickness, as summarized in Table I. FIG. 3, parts a and b, show the comparison between QDs grown under different durations. As can be seen, longer growth duration increases both the dot density and size. Meanwhile, the aspect ratio remains similar for QDs grown with different durations. The measured smallest dot height is about 2 nm, corresponding to 8 monolayers of GaN. FIG. 3, parts c and d, are AFM images of samples grown under different III/V ratios. It was observed that with nitrogen flow rate increasing from 0.5 to 2 sccm, the GaN quantum dot density on the hBN monolayers increases by nearly one order of magnitude. This indicates that in vdW epitaxy, higher nitrogen flow rate enhances the nucleation probability on the surface. The aspect ratio also increases with increasing nitrogen flow rate.

TABLE I
Density, mean aspect ratio and mean thickness of GaN QDs on various substrates

| | Growth | Nitrogen | Density | Mean aspect | Mean |
|---|---|---|---|---|---|
| Substrate | duration (mins) | flow ( [symbol] ) | (/cm²) | ratio (D/H) | thickness (nm) |
| hBN | 5 | 1 | 4 × 10⁸ | 3.1 | 2.7 |
| | 10 | | 1.7 × 10⁹ | 2.5 | 5.3 |
| | 20 | | 2.6 × 10⁹ | 2.64 | 7.9 |
| | 30 | | 7 × 10⁹ | 2.7 | 12 |
| | 20 | 0.5 | 1.7 × 10⁹ | 3.3 | 4.1 |
| | | 1 (Sample A) | 2.6 × 10⁹ | 2.64 | 7.9 |
| | | [symbol] | 1.6 × 10¹⁰ | 1.7 | 12 |
| AlN | 5 (Sample B) | | 2 × 10 [symbol] | 2 | 2.8 |
| SiN [symbol] | 5 (Sample C) | 1 | 1.25 × 10¹⁰ | 1.6 | 10.8 |

[symbol]

indicates data missing or illegible when filed

The crystallographic orientations between the GaN QDs and hBN monolayers were further investigated by increasing growth duration to 50 mins, at which the GaN QDs evolves into faceted-nanocrystals due to anisotropies in the surface energies in the different directions. As shown in the top-view SEM image of FIG. 4, part a, arrow-headed shapes were observed lying on the hBN monolayers, in which the pointing (flat) end of the nanocrystal matches the features of Ga (N)-polar surface of wurtzite GaN. Therefore, the c-axis of the horizontal nanocrystal is perpendicular to the c-axis direction of hBN, which is the same as shown in FIG. 2, part d. The inset of FIG. 4, part a, labels various facets that are clearly observed from the nanocrystals. FIG. 4, part b, is the low-magnification SEM image showing both a triangular hBN flake and GaN nanocrystals on top. The c-axis of several horizontal nanocrystals (outlined by dashed circles) was surveyed and summarized by the three arrows in FIG. 4, part b. As can be seen, the arrows are along the <112̅0> directions of the hBN material. Vertical nanocrystals with hexagonal cross section were also observed as indicated by yellow dashed circles, which resembles wurtzite GaN with a c-axis orthogonal or vertical to the substrate and sidewalls composed of m-planes.

Based on these results, analysis on the crystallographic alignment between GaN QDs and hBN is provided. The in-plane lattice constant is 0.25 nm for hBN and 0.3189 nm for GaN. The out-of-plane lattice constant is 0.5189 nm for GaN. For horizontal nanocrystals, along the <112̅0> directions of hBN, one can notice a good coincidence between the two lattices every 5 unit cells of GaN and 12 unit cells of hBN as depicted in FIG. 4, part c. The residue misfit associated with this coincidence is about 2%, which is compatible with strain. On the other hand, along the c-axis of the two lattices, a good coincidence between every 4 unit cells of GaN and 6 unit cells of hBN can be observed, as depicted in FIG. 4, part d. The residue misfit associated with this coincidence is about −3.5%. The multiplicity of crystallographic orientations of GaN QDs grown on hBN further establishes the fundamentally different nature of vdW epitaxy compared with covalent epitaxy.

The optical properties of the GaN QDs on hBN and AlN materials or substrates were then investigated through detailed PL measurements, in which a pulsed ArF excimer laser with excitation photon energy of 6.42 eV was utilized. FIG. 5, part a, shows the PL spectra measured from the GaN QDs of samples A (on hBN), B (on AlN) and C (on SiNₓ) at 12 K under excitation power density of 7.4 mW/cm². The emission from GaN QDs on hBN, namely the 3.54 eV peak, was seen to have an intensity that is more than 4 times stronger than its counterparts on AlN and SiNₓ despite the QD density on the hBN material being nearly 2 orders of magnitude lower. The average volume of the GaN quantum dot structures within the excitation spot of Sample A was nearly 2 orders of magnitude lower than that of Samples B and C, indicating a superior optical quality.

Temperature dependent measurements were performed on the QDs of samples A and B. As shown in FIG. 5, part b, the GaN peak energies of sample B follow an S-shape. The S-shape has been observed in InGaN/GaN quantum well structures and quantum dot structures and attributed to charge carrier redistribution among localized states with different bonding energies. In contrast, the measured PL peak energies of GaN QDs on the hBN material decreases monotonically with temperatures. The Varshni empirical equation, Eₒ(T)=Eₒ(0)−αT²/(β+T) was used to fit the experimental data. Eₒ(0) is the transition energy at 0 K and α and β are known as Varshni's thermal coefficient and the Debye temperature, respectively. The obtained best fit parameters are Eₒ(0)=3.49 eV, α=5×10⁻⁴ eV/K and β=732.5 eV/K for the GaN QDs on hBN. These values are in close agreement with those reported before. The lack of blue shift indicates that GaN QDs grown on hBN are free of localized states. The weak atomic interactions in vdW epitaxy along with the absence of a wetting layer enhances the quantum confinement of charge carriers within the QDs and thus leads to an efficient radiative recombination process.

To further confirm this, power-dependent PL measurements were performed at room temperature. The excitation power was varied over 2-3 orders of magnitude. The following set of rate equations was utilized to analyze the experimental data and the radiative and nonradiative recombination processes:

$$G = A n + B {n}^{2} + C {n}^{3} \qquad ( 1 )$$

$${I}_{P L} = θ B {n}^{2} \qquad ( 2 )$$

$$IQE = \frac{B {n}^{2}}{G} , \qquad ( 3 )$$

in which G is the steady state generation/recombination rate, I_{PL} is the integrated PL intensity, n is the photogenerated carrier concentration within hBN, and θ is a constant determined by the measurement setup. A is the nonradiative recombination coefficient, B is the radiative recombination coefficient and C is the coefficient related to Auger recombination, and I_{PL} is the integrated PL intensity. Here G can be further expressed as:

$$G = \frac{α ( 1 - R )}{{A}_{spot} {E}_{p h}} {P}_{ex} , \qquad ( 4 )$$

in which Pₑₓ, Aₛₚₒₜ and Eₚₕ are the laser excitation power, excitation area, and excitation photon energy, respectively. α and R are the absorption coefficient and Fresnel reflection coefficient of bulk GaN and the substrate, respectively. In this study, we used α=2.6×10⁵ cm⁻¹ based on previous reports, R=0.3 for hBN on nickel and R=0.4 for AlN on sapphire determined by reflection measurements. Based on equation (2), one could express n as a function of I_{PL}^{0.5}. Then, θ can be determined with equations (2) and (3), assuming the IQE at 13 K to be unity. Then, the relation between G and I_{PL} can be studied with A/B^{0.5} and C/B^{1.5} as fitting parameters which vary only with temperature.

FIG. 5, part d, shows the measured G vs I_{PL} for sample A and sample B as well as the fitting results. The obtained A/B^{0.5} values are one order of magnitude lower in sample A than that of sample B. Assuming the radiative recombination coefficient is similar in both samples, the nonradiative Shockley-Read-Hall (SRH) recombination is significantly less in the GaN QDs on hBN, further establishing the superior optical quality of the GaN QDs on hBN due to the weak atomic interactions.

The examples described herein show that 2D, layered hBN is a useful supporting material or substrate for GaN QD growth. The vdW epitaxy of GaN QDs on the layered hBN has been achieved under nitrogen rich growth conditions. Wetting layer free GaN QDs with controllable size and density have been successfully grown on hBN. Unique structural and optical properties were observed from GaN QD/hBN heterostructures. Unlike the fixed crystallographic alignment in QDs covalently bonded to substrates, multiple orientations were observed from QDs on hBN, in which the [0001] direction of wurtzite GaN is parallel to either the <1120> or [0001] directions of the hBN flakes. The two materials are strained to accommodate a 2% misfit ensuring a certain lattice coincidence. Moreover, PL intensity obtained from GaN QDs/hBN is 4 times stronger than that of QDs grown on AlN and Si substrates despite the significantly reduced QD density, showing a highly efficient radiative recombination process. Temperature and power-dependent measurements also show that QDs on hBN are free of localized states and have significantly less Shockley-Reed-Hall recombination. These results provide unambiguous evidence that the use of hBN substrate can significantly improve the optical quality of QDs and provide a new strategy for next-generation high-performance quantum light sources.

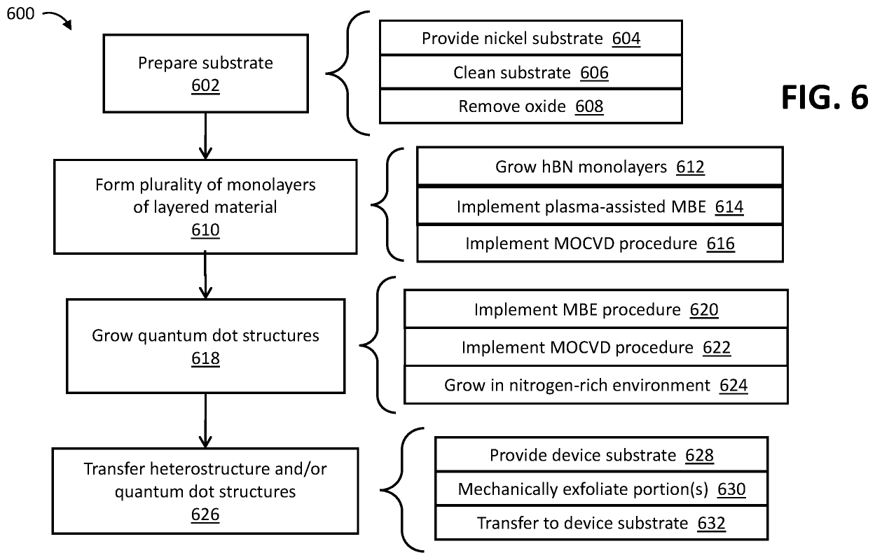

FIG. 6 depicts a method 600 of fabricating a quantum dot or other device having a heterostructure in accordance with one example. As described herein, the method 600 may be configured such that the heterostructure lacks a wetting layer. The heterostructure may form a device, or a part of a device, such as a light emitting or other optoelectronic device. In other cases, the quantum dot or other device is a quantum computing or other electronic device. The method 600 may be used to fabricate the device examples of described herein, as well as other heterostructures.

The method 600 may begin with an act 602 in which a substrate is prepared and/or otherwise provided. In some cases, the act 602 includes providing a nickel substrate (e.g., a polycrystalline nickel substrate) in an act 604. Alternative or additional materials may be used, including, for instance, graphene or graphite. Still other materials may be used, including, for instance, BN.

The substrate may be cleaned in an act 606. For instance, the substrate may be cleaned via dips in acetone, methanol, and DI water. Organic impurities may thus be removed. In some cases, a native or other oxide layer may be removed from a substrate surface in an act 608. Additional or alternative processing may be implemented in other cases, including, for instance, degassing (e.g., via thermal degassing), doping or deposition procedures. The substrate thus may or may not have a uniform composition. The substrate may be a uniform or composite structure.

In an act 610, a layered material is formed. The layered material includes a plurality of monolayers, as described herein. As a layered material, adjacent monolayers of the plurality of monolayers being bonded to one another via van der Waals forces. In some cases, the monolayers are epitaxially grown in a growth chamber. The monolayers are thus formed on, or otherwise supported by, the substrate. In some cases, one of the monolayers is in contact with the substrate. In other cases, an intermediary layer is disposed between the semiconductor layer and the substrate. The intermediary layer may be composed of, or otherwise include, graphene, MoS₂, or other layered materials.

As described herein, the layered material may have a thickness sufficient to support the van der Waals epitaxy of the quantum dot structures of the heterostructure. For instance, in cases in which the substrate is composed of, or otherwise includes, a covalently bonded material, the act 610 may include implementing a growth procedure configured to grow a number of monolayers sufficient to screen the set of quantum dot structures from a potential field of the covalently bonded material.

Epitaxially growing the layered material may include implementing a growth procedure configured for van der Waals epitaxy. For instance, the growth procedure may be configured for growth of hBN monolayers in an act 612. In some cases, the act 610 includes implementation of a plasma-assisted MBE procedure in an act 614. For instance, the layers grown in the act 614 (and/or other growth acts described herein) may use a Veeco GENxplor MBE system, equipped with a radio frequency (RF) nitrogen plasma source for active nitrogen supply (N′). Alternative or additional procedures may be implemented, including, for instance, a MOCVD procedure in an act 616.

The layered material may be composed of, or otherwise include, hBN. Alternative or additional layered materials may be formed in the act 610. For instance, monolayers of MoS₂ and MoSe₂ may be formed. Still other layered materials may be formed, including, for instance, graphene, MoSe₂, WS₂, or WSe₂. The layered material and the substrate may or may not have a chemical composition in common.

Further details regarding examples of the epitaxial growth or other formation of the layered material are set forth in Laleyan et al., “Effect of growth temperature on the structural and optical properties of few-layer hexagonal boron nitride by molecular beam epitaxy,” Vol. 26, No. 18|3, Optics Express, pp. 23031-23039 (2018), the entire disclosure of which is hereby incorporated by reference.

The method 600 includes an act 618 in which a set of quantum dot structures or nanocrystals of the heterostructure are epitaxially grown. Each quantum dot structure (or nanocrystal) is composed of, or otherwise includes, a semiconductor material. In some cases, the quantum dot structures (or nanocrystals) grown in the act 618 are composed of, or otherwise includes, a III-nitride semiconductor material, such as GaN, but alternative or additional semiconductor materials may be used, including, for instance, other III-nitride semiconductor materials, such as InN and AlN and alloys thereof. Still other III-V materials and other semiconductor materials may be used.

Growing the set of quantum dot structures (or nanocrystals) is implemented after forming the layered material in the act 610 such that the layered material is disposed between the set of quantum dot structures and the substrate and, as described herein, such that the semiconductor material of each quantum dot structure of the set of quantum dot structures exhibits bonding with the layered material via van der Waals forces. The set of quantum dot structures are thus not grown upon a wetting layer, as also described herein.

The act 618 may include an act 620 in which the semiconductor layer is grown via implementation of an MBE procedure. Alternatively, a MOCVD procedure is implemented in an act 622. In either case, the growth may be continued in the same chamber used in the act 610 is used to grow the layered material.

In some cases, the act 618 includes an act 624 in which the epitaxial growth is implemented in a nitrogen-rich environment, e.g., under nitrogen-rich conditions. In one example, the radio-frequency nitrogen plasma source was employed at a power 350 W and with a Nitrogen flow rate in the range of 0.8-1 sccm. The beam equivalent pressure (BEP) of Ga is about 3 e-8 Torr. The nitrogen and Ga shutters were opened simultaneously without any seeding processes. In that example, GaN QDs were grown for 20 minutes at a thermal couple reading of 845° C. on a 1 cm-by-1 cm hBN/Ni substrate.

Other growth temperatures may be used. For instance, growing the set of quantum dot structures may be implemented at a temperature falling in a range from about 600° C. to about 850° C. degrees Celsius, but other growth temperatures may be used (e.g., in connection with the growth of other semiconductor materials). Other growth parameters may vary as well.

The method 600 may include an act 626 in which the heterostructure or a portion thereof (e.g., the quantum dot structures) is transferred from a growth substrate to another substrate (e.g., a device substrate). The device substrate may have a composition and/or other characteristics unsuitable (or less suitable) for growth of the heterostructure, but well-suited (or more well-suited) for operation or application. For instance, the device substrate may be flexible or bendable or have other structural characteristics tailored for a device application. Alternatively or additionally, the device substrate may have one or more optical or other electromagnetic characteristics tailored for a device application, such as being transparent (or opaque) or conducting (or non-conducting). As used herein, terms such as “transparent” and “conducting” are used in the context of the device functionality or application such that, for instance, the device substrate is transparent at wavelengths relevant to the functionality or application of the device. Transfer to a device substrate may be useful for additional or alternative purposes, including, for instance, hetero-integration, e.g., with one or more other structures, layers, or other elements. For example, the quantum dot structures may be transferred to a device substrate to function as active materials or components. Alternatively, the quantum dot structures may be transferred for use as passivation elements, such as for color conversion.

In the example of FIG. 6, the act 626 may include an act 628 in which the device substrate is provided. A wide variety of materials may be used for the device substrate, including, for instance, GaN (or other III-V semiconductor material), Si, silicon-on-insulator (SOI), sapphire, indium tin oxide (ITO), a polymer material, glass, or a foil material (e.g., metal foil). In the example of FIG. 6, the act 626 may include an act 628 in which the device substrate of a desired composition and/or configuration is provided.

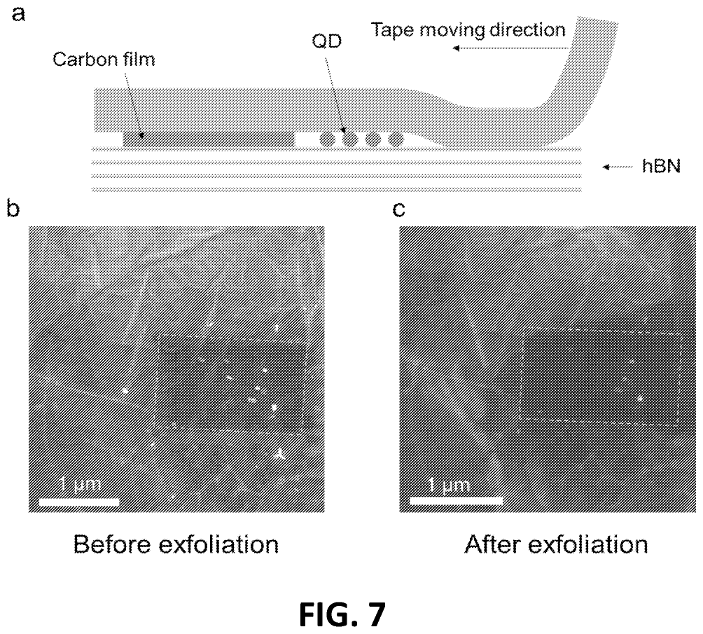

In some cases, transferring the heterostructure or a portion thereof may include an act 630 in which the transferred portion is mechanically exfoliated. In some cases, the mechanical exfoliation may be performed on the as-grown GaN quantum dot structures using polyimide tape. In one example involving GaN quantum dots on a triangular hBN flake, all of the quantum dots were exfoliated, thereby confirming the weak van der Waals interaction between the GaN quantum dots and the hBN flake. The mechanical exfoliation exclusively removes the GaN quantum dots without affecting the underlying 2D hBN flake. Further details regarding the exfoliation are provided below in connection with FIG. 7. Alternative or additional techniques for removal of the heterostructure or quantum dot structures may be used in other cases.

The heterostructure or quantum dot structures may be transferred to the device substrate in an act 632. In such cases, the heterostructure or quantum dot structures exhibit bonding with the device substrate via van der Waals forces. For instance, the semiconductor material of the quantum dot structures may exhibit bonding with the device substrate via van der Waals forces. The heterostructure or quantum dot structures may thus be in contact with the device substrate. The manner in which the transfer is achieved may thus vary, e.g., in connection with the composition and/or other characteristics of the device substrate.

The method 600 may include one or more additional acts. For instance, one or more acts may be configured or directed to forming additional layers of the heterostructure or other structures of the device. In some cases, one or more metal layers may be deposited and patterned to form one or more contacts or electrodes.

The method 600 may include fewer, alternative, or additional acts. For example, the method 600 may include the implementation of one or more doping procedures for one or more of the semiconductor elements described herein. Such doping may be useful in connection with charge carrier confinement and/or other purposes. The method 600 may also include any number of additional acts directed to forming additional layers of the heterostructure or other structures of the device. In some cases, one or more metal layers may be deposited and patterned to form one or more contacts or electrodes.

FIG. 7 depicts an example of mechanical exfoliation of GaN quantum dot structures using polyimide tape. In this case, only GaN vQDs/nanocrystals are exfoliated instead of the underlying hBN. To confirm such selective exfoliation, parts of the GaN quantum dot structures on the hBN layers were selectively covered by a thin layer of carbon while other quantum dot structures were left as-grown. The carbon-covered quantum dot structures are more difficult to exfoliate due to the strong adhesion energy between the carbon film and the hBN and therefore, only the as-grown quantum dot structures will be removed if the exfoliation exclusively affects quantum dot structures. If the polyimide tape also removes the top or first several layers of hBN, anything on top of the hBN should also be removed, including the covered and as-grown quantum dot structures.

As shown in part (b) of FIG. 7, the GaN quantum dot structures/nanocrystals within the dashed rectangle are covered by a thin layer of carbon deposited by electron-beam-induced deposition (EBID). After mechanical exfoliation, as shown in part (c) of FIG. 7, the covered GaN quantum dot structures/nanocrystals remain on top of the hBN layers while the as-grown ones, i.e., outside the dashed rectangle, are almost all removed, which unambiguously confirms the weak van der Waals interaction between GaN quantum dot structures and the hBN layers.

The exfoliation allows free-standing quantum dot structures and subsequent transfer to other functional substrates. Such transfer may be used to form a variety of integrated optoelectronic and quantum devices.

With reference again to part (d) of FIG. 1, the device 100 includes a heterostructure 102 in accordance with one example. The device 100 may be fabricated via the method 600 of FIG. 6 and/or another method. In some cases, the device 100 is configured as a light emitting device or other optoelectronic device. In other cases, the device 100 is configured as a computing or other electronic device.

The device 100 includes a substrate 104 and a heterostructure 102 supported by the substrate 104. The heterostructure 102 includes a set of quantum dot structures (or nanocrystals) 106. In the example of FIG. 1, the quantum dot structures (or nanocrystals) 106 are schematically shown as a layer of GaN. Each quantum dot structure (or nanocrystal) 106 of the set of quantum dot structures (or nanocrystals) includes a semiconductor material, such as GaN, but alternative or additional semiconductor materials may be used.

The substrate 104 may be composed of, or otherwise include, nickel, but alternative or additional materials may be used, including for instance, graphene or graphite. In this example, the heterostructure 102 is in contact with the substrate 104. In other cases, one or more layers are disposed between the substrate 104 and the heterostructure 102.

The heterostructure 102 further includes a layered material 108 disposed between the set of quantum dot structures 106 and the substrate 104. The layered material 106 includes a plurality of monolayers 108 such that adjacent monolayers 108 of the plurality of monolayers are bonded to one another via van der Waals forces, and such that the semiconductor material of each quantum dot structure (or nanocrystal) 106 of the set of quantum dot structures (or nanocrystals) exhibits bonding with the layered material via van der Waals forces. In the example of FIG. 1, the layered material 108 is schematically shown as including two or more monolayers 110 of hBN. Alternative or additional layered materials may be used, as described herein.

In some cases, the substrate 104 is composed of, or otherwise includes, a covalently bonded material. In such cases, the layered material 108 has a number of monolayers 110 sufficient to screen the set of quantum dot structures (or nanocrystals) 106 from a potential field of the covalently bonded material. Accordingly, and as described herein, each quantum dot structure (or nanocrystal) 106 of the set of quantum dot structures (or nanocrystals) may be bonded to one of the plurality of monolayers 110 via van der Waals forces. The heterostructure 102 thus lacks a wetting layer (e.g., a wetting layer between the quantum dot structures 106 and the substrate 104). The quantum dot structures (or nanocrystals) 106 may also thus exhibit multiple crystallographic orientations.

In the example of FIG. 1, the heterostructure 102 is in contact with the substrate 104. Each quantum dot structure 106 of the set of quantum dot structures is in contact with a first (e.g., top) monolayer 110 of the plurality of monolayers. A second (e.g., bottom) monolayer 110 of the plurality of monolayers is in contact with the substrate 104. In other cases, one or more intermediate layers may be present.

In some cases, the substrate 104 of the device 100 may correspond with a device substrate to which the heterostructure 102 (or a portion thereof) has been transferred, as described above. For example, the quantum dot structures 106 may be transferred to a device substrate. As a result, the quantum dot structures 106 may be in contact with the substrate 104. As described above, the substrate 104 may exhibit one or more properties (e.g., conductive, transparent, etc.) in support of the device functionality.

Described above are examples of methods and devices involving a new class of QD heterostructures that overcome the fundamental limitations of current approaches to QD formation. Such current approaches generally involve the use of etching, Stranski-Krastanov (SK) growth mode, or solution processing, each of which exhibit very limited material quality. For example, SK QD formation is driven by the large lattice mismatch between the QD active region and the underlying substrate, resulting in the formation of a two-dimensional wetting layer as well as interfacial defects and large size dispersion, which severely limits the application of QDs. By utilizing hexagonal boron nitride (hBN) as a supporting material or substrate, the disclosed methods are capable of forming van der Waals GaN quantum dots without the presence of a two-dimensional wetting layer. Moreover, the GaN QDs are free of dislocations and stacking faults due to the van der Walls interfacial interaction. Compared to GaN QDs formed on AlN or Si substrates, van der Waals QDs grown on hBN monolayers exhibit drastically improved optical quality. For instance, the photoluminescence emission intensity for examples of QDs on hBN was four times stronger despite having a QD density nearly two orders of magnitude lower. Enhanced growth duration further leads to the formation of GaN nanocrystals, which show multiple crystallographic orientations through vdW interactions. The disclosed devices and methods accordingly provide a new strategy for synthesizing high quality QD structures, which, in turn, support or enable next-generation high performance optoelectronic and other quantum devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate; and
a heterostructure supported by the substrate, the heterostructure comprising:
a set of quantum dot structures, each quantum dot structure of the set of quantum dot structures comprising a semiconductor material; and
a layered material disposed between the set of quantum dot structures and the substrate;
wherein the layered material comprises a plurality of monolayers such that
adjacent monolayers of the plurality of monolayers are bonded to one another via van der Waals forces, and
the semiconductor material of each quantum dot structure of the set of quantum dot structures exhibits bonding with the layered material via van der Waals forces.

2. The device of claim 1, wherein:
the substrate comprises a covalently bonded material; and
the layered material has a number of monolayers sufficient to screen the set of quantum dot structures from a potential field of the covalently bonded material.

3. The device of claim 1, wherein the heterostructure lacks a wetting layer.

4. The device of claim 1, wherein each quantum dot structure of the set of quantum dot structures is bonded to one of the plurality of monolayers via van der Waals forces.

5. The device of claim 1, wherein the quantum dot structures exhibit multiple crystallographic orientations.

6. The device of claim 1, wherein the heterostructure is in contact with the substrate.

7. The device of claim 1, wherein:
each quantum dot structure of the set of quantum dot structures is in contact with a first monolayer of the plurality of monolayers;
a second monolayer of the plurality of monolayers is in contact with the substrate.

8. The device of claim 1, wherein the semiconductor material is a III-V material.

9. The device of claim 1, wherein the semiconductor material is a III-nitride material.

10. The device of claim 1, wherein the semiconductor material is GaN.

11. The device of claim 1, wherein the layered material is hexagonal boron nitride.

12. The device of claim 1, wherein the substrate comprises polycrystalline nickel.

13. The device of claim 1, wherein the substrate and the layered material have a chemical composition in common.

14. A method of fabricating a quantum dot device, the method comprising:
forming a layered material, the layered material comprising a plurality of monolayers supported by a substrate, with adjacent monolayers of the plurality of monolayers being bonded to one another via van der Waals forces; and
growing epitaxially a set of quantum dot structures, each quantum dot structure of the set of quantum dot structures comprising a semiconductor material;
wherein growing the set of quantum dot structures is implemented after forming the layered material such that
the layered material is disposed between the set of quantum dot structures and the substrate, and
the semiconductor material of each quantum dot structure of the set of quantum dot structures exhibits bonding with the layered material via van der Waals forces.

15. The method of claim 14, wherein:
the semiconductor material comprises a III-nitride material; and
growing the set of quantum dot structures is implemented in a nitrogen-rich environment.

16. The method of claim 15, wherein growing the set of quantum dot structures is implemented at a temperature falling in a range from about 600°° C. to about 850° C. degrees Celsius.

17. The method of claim 14, wherein forming the layered material comprises epitaxially growing the layered material.

18. The method of claim 17, wherein epitaxially growing the layered material comprises implementing a growth procedure configured for van der Waals epitaxy.

19. The method of claim 17, wherein:
the substrate comprises a covalently bonded material; and
epitaxially growing the layered material comprises implementing a growth procedure configured to grow a number of monolayers sufficient to screen the set of quantum dot structures from a potential field of the covalently bonded material.

20. The method of claim 14, wherein the set of quantum dot structures are not grown upon a wetting layer.

21. A device comprising:
a substrate; and
a heterostructure supported by the substrate, the heterostructure comprising:
a set of nanocrystals, each nanocrystal of the set of nanocrystals comprising a semiconductor material; and
a layered material disposed between the set of nanocrystals and the substrate;
wherein the layered material comprises a plurality of monolayers such that
adjacent monolayers of the plurality of monolayers are bonded to one another via van der Waals forces, and
the semiconductor material of each nanocrystal of the set of nanocrystals exhibits bonding with the layered material via van der Waals forces.

22. A method of fabricating a device, the method comprising:
forming a layered material, the layered material comprising a plurality of monolayers supported by a substrate, with adjacent monolayers of the plurality of monolayers being bonded to one another via van der Waals forces; and
growing epitaxially a set of nanocrystals, each nanocrystal of the set of nanocrystals comprising a semiconductor material;
wherein growing the set of nanocrystals is implemented after forming the layered material such that
the layered material is disposed between the set of nanocrystals and the substrate, and
the semiconductor material of each nanocrystal of the set of nanocrystals exhibits bonding with the layered material via van der Waals forces.

23. A device comprising:
a substrate; and
a set of quantum dot structures supported by the substrate, each quantum dot structure of the set of quantum dot structures comprising a semiconductor material;
wherein the semiconductor material of each quantum dot structure of the set of quantum dot structures exhibits bonding with the substrate via van der Waals forces.

24. The device of claim 23, wherein the set of quantum dot structures are in contact with the substrate.

25. The device of claim 23, wherein the substrate comprises silicon.

26. The device of claim 23, wherein the substrate is transparent.
